(19) United States
(12) Patent Application Publication
(10) Pub. No.: US 2013/0065377 A1
(43) Pub. Date: Mar. 14, 2013

(54) INTERFACE LAYER IMPROVEMENTS FOR NONVOLATILE MEMORY APPLICATIONS

(71) Applicants: Vidyut Gopal, Sunnyvale, CA (US); Yun Wang, San Jose, CA (US); Imran Hashim, Saratoga, CA (US)

(72) Inventors: Vidyut Gopal, Sunnyvale, CA (US); Yun Wang, San Jose, CA (US); Imran Hashim, Saratoga, CA (US)

(73) Assignee: INTERMOLECULAR, INC., San Jose, CA (US)

(21) Appl. No.: 13/228,744

(22) Filed: Sep. 9, 2011

(51) Int. Cl. H01L 47/00

(52) U.S. Cl. 438/382; 257/E47.005

(57) ABSTRACT

A resistive switching nonvolatile memory device having an interface layer disposed between a doped silicon electrode and a variable resistance layer fabricated in the nonvolatile memory device and methods of fabricating the same. In one embodiment, the interface layer is a high-k layer having a lower electrical EOT than native silicon oxide to act as a diffusion barrier between the variable resistance layer and the silicon electrode. Alternatively, the high-k interface layer may be formed by performing a nitrogen treatment on a fabricated silicon oxide layer. In another embodiment, the interface layer may be fabricated by performing a nitrogen or ozone treatment on the native oxide layer. In another embodiment, the interface layer is a fabricated silicon oxide layer resulting in an improved diffusion barrier between the variable resistance layer and the silicon electrode. In all embodiments, the interface layer also passivates the surface of the silicon electrode.

### BACKGROUND OF THE INVENTION

1. Field of the Invention

wan This invention relates to nonvolatile memory elements, and more particularly, to methods for forming resistive switching memory elements used in nonvolatile memory devices.

2. Description of the Related Art

Nonvolatile memory elements are used in systems in which persistent storage is required. For example, digital cameras use nonvolatile memory cards to store images and digital music players use nonvolatile memory to store audio data. Nonvolatile memory is also used to persistently store data in computer environments.

Nonvolatile memory is often fabricated using electrically-erasable programmable read only memory (EPROM) technology. This type of nonvolatile memory contains floating gate transistors that can be selectively programmed or erased by application of suitable voltages to their terminals.

As fabrication techniques improve, it is becoming possible to fabricate nonvolatile memory elements with increasingly small dimensions. However, as device dimensions shrink, scaling issues are posing challenges for traditional nonvolatile memory technology. This has led to the investigation of alternative nonvolatile memory technologies, including resistive switching nonvolatile memory.

Resistive switching nonvolatile memory is fabricated using memory elements that have two or more stable states with different resistances. Bistable memory has two stable states. A bistable memory element can be placed in a high resistance state or a low resistance state by application of suitable voltages or currents. Voltage pulses are typically used to switch the memory element from one resistance state to the other. Nondestructive read operations can be performed to ascertain the value of a data bit that is stored in a memory cell.

Resistive switching based on transition metal oxide switching elements fabricated of metal oxide (MO) films has been demonstrated. Although metal oxide films such as these exhibit bistability, the resistance of these films and/or the ratio of the high-to-low resistance states is (are) often insufficient to be of use within a practical nonvolatile memory device. For instance, the resistance states of the metal oxide film should preferably be significant as compared to that of the system (e.g., the memory device and associated circuitry) so that any change in the resistance state change is perceptible. Since the variation in the difference between the high and low resistive states is related to the resistance of the resistive switching layer, it is often hard to use a low resistance metal oxide film to form a reliable nonvolatile memory device.

For example, in a nonvolatile memory that has conductive lines fabricated of a relatively high resistance metal such as tungsten, the resistance of the conductive lines may overwhelm the resistance of the metal oxide resistive switching element. This may make it difficult or impossible to sense the state of the bistable metal oxide resistive switching element. Similar issues can arise from integration of the resistive switching memory element with current steering elements, such as diodes and/or resistors. The resistance of the resistive switching memory element (at least in its high resistance state) is preferably significant compared to the resistance of the current steering elements, so that the unvarying resistance of the current steering element does not dominate the resistance of the switching memory element, and thus reduce the measurable difference between the “on” and “off” states of the fabricated memory device (i.e., logic states of the device). However, since the power that can be delivered to a circuit containing a series of resistive switching memory elements and current steering elements is typically limited in most conventional nonvolatile memory devices (e.g., CMOS driven devices), it is desirable to form each of the resistive switching memory elements and current steering elements in the circuit so that the voltage drop across each of these elements is small, and thus resistance of the series connected elements does not cause the current to decrease to an undesirable level due to the fixed applied voltage (e.g., ˜2-5 volts).

As nonvolatile memory device sizes shrink, it is important to reduce the currents and voltages that are necessary to reliably set, reset and/or determine the desired “on” and “off” states of the device to minimize resistive heating of the device and cross-talk between adjacent devices. Moreover, in cases where multiple fabricated memory devices are interconnected to each other and to other circuit elements it is desirable to minimize the device performance variation between one device to the next to assure that the performance of the fabricated circuit performs in a desirable manner.

Therefore, it is desirable to form a nonvolatile memory device that has a low operating current and reduced device performance variability.

### SUMMARY OF THE INVENTION

Embodiments of the present invention generally provide methods of fabricating a resistive switching nonvolatile memory device having an engineered interface layer disposed between a highly doped silicon electrode and a variable resistance layer in order to reduce the operating current of the device.

In one embodiment of the present invention, a method of fabricating a nonvolatile memory element comprises removing at least a portion of a native oxide layer from a surface of a first electrode, fabricating a high-k interface layer above the surface of the first electrode from which the native oxide was removed, fabricating a variable resistance layer over the high-k interface layer, and fabricating a second electrode over the variable resistance layer. The first electrode comprises silicon.

In another embodiment, a method of fabricating a nonvolatile memory element comprises performing a nitrogen or ozone treatment above a native oxide layer disposed on a first electrode, fabricating a variable resistance layer over the first electrode, and fabricating a second electrode over the variable resistance layer.

In another embodiment, a method of fabricating a nonvolatile memory element comprises removing a native oxide layer from a first electrode, fabricating an oxide layer on the first electrode, fabricating a variable resistance layer over the first electrode, and fabricating a second electrode over the variable resistance layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an array of resistive switching memory elements according to one embodiment.

FIG. 2A is schematic representation of a memory device according to one embodiment.

FIG. 2B is schematic representation of a memory device having a diode type current steering element according to one embodiment.

FIG. 2C is schematic representation of an array of memory devices according to one embodiment.

FIG. 2D is a current (I) versus voltage (V) plot for a memory element according to one embodiment.

FIG. 3 is a schematic side cross-sectional views of a nonvolatile memory device in according to one embodiment.

FIGS. 4A-4E are partial schematic depictions of the switching memory device of FIG. 3 at various stages of formation.

FIG. 5 is a schematic depiction of a process for forming the switching memory device as depicted in FIGS. 4A-4E.

FIG. 6 is a schematic illustration of the band structure of an interface fabricated between an intermediate electrode and a variable resistance layer having an interface layer fabricated therebetween.

While the foregoing is directed to embodiments of the present invention, other and further embodiments of the invention may be devised without departing from the basic scope thereof, and the scope thereof is determined by the claims that follow.

### DETAILED DESCRIPTION

Embodiments of the invention generally relate to a resistive switching nonvolatile memory device having an interface layer disposed between a highly doped silicon electrode and a variable resistance layer fabricated in the nonvolatile memory device, and methods of fabricating the same. In one embodiment, the interface layer is a high-k layer having a lower electrical effective oxide thickness than native silicon oxide to act as a diffusion barrier between the variable resistance layer and the silicon electrode. The high-k interface layer also increases the barrier height for electron injection/tunneling at the interface between the silicon electrode and the variable resistance layer, which inhibits the flow of current at the interface, reducing switching currents and voltages of the nonvolatile memory device. In another embodiment, the interface layer is a fabricated silicon oxide layer resulting in an improved diffusion barrier between the variable resistance layer and the silicon electrode. In both embodiments, the interface layer also passivates the surface of the silicon electrode.

In one embodiment, a native silicon oxide layer residing on the silicon electrode is removed prior to fabricating the interface layer on the silicon electrode. In another embodiment, a nitrogen or ozone treatment is performed on a native silicon oxide layer prior to fabricating the variable resistance layer. In another embodiment, a nitrogen treatment is performed on a fabricated silicon oxide layer to convert it to a silicon nitride layer prior to fabricating the variable resistance layer. In another embodiment, an ozone treatment is performed either prior to or after fabricating the variable resistance layer. In yet another embodiment, the fabricated silicon oxide layer is formed by a chemical oxide treatment.

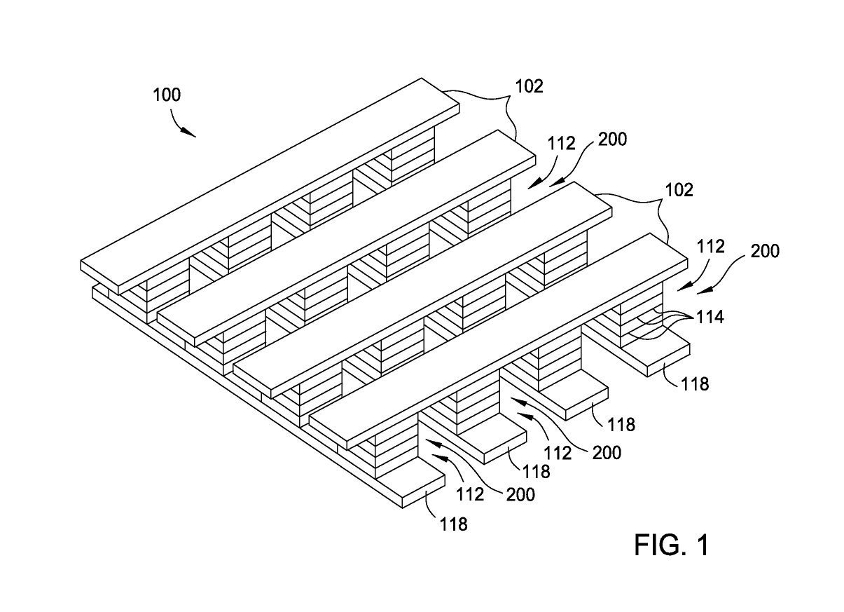

An illustrative memory array 100 of nonvolatile resistive switching memory devices 200, which each generally include at least one switching memory element 112, is illustrated in FIG. 1. Memory array 100 may be part of a larger memory device or other integrated circuit structure, such as a system on a chip type device. Read and write circuitry is connected to switching memory devices 200 using electrodes 102 and orthogonal electrodes 118. Electrodes, such as electrodes 102 and electrodes 118, are sometimes referred to as word lines and bit lines, and are used to read and write data into the memory elements 112 in the switching memory devices 200. Individual switching memory devices 200 or groups of switching memory devices 200 can be addressed using appropriate sets of electrodes 102 and 118. The memory elements 112 in the switching memory devices 200 may be fabricated from one or more layers 114 of materials, as shown schematically in FIG. 1. In addition, memory arrays such as memory array 100 can be stacked in a vertical fashion to make multilayer memory array structures.

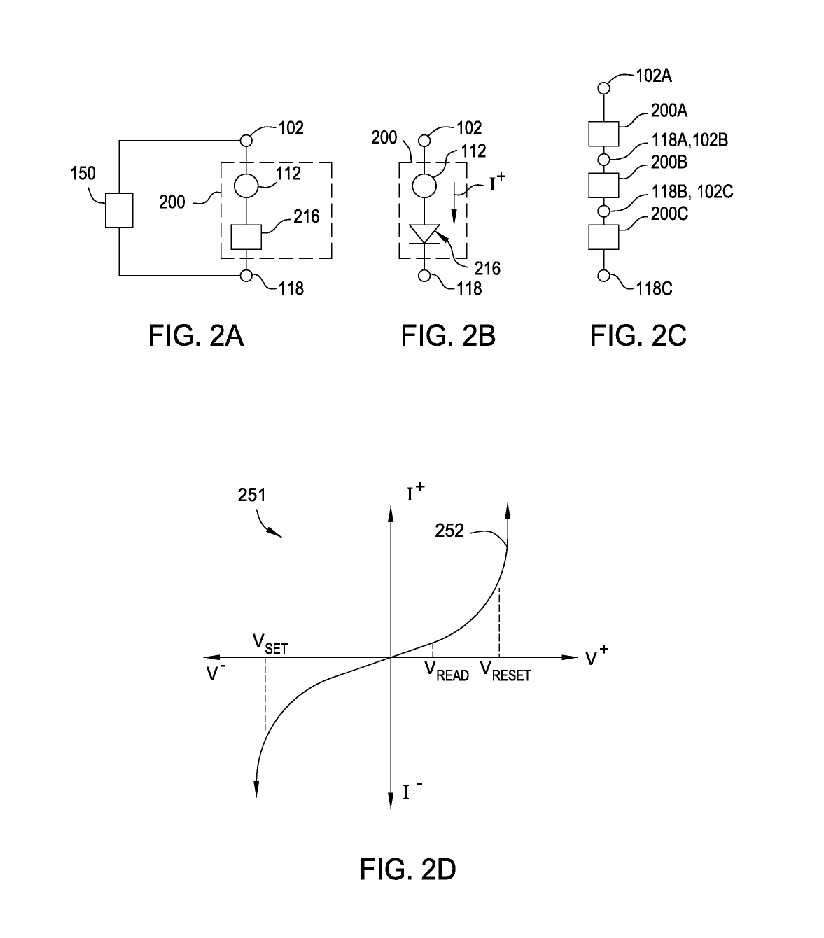

FIG. 2A schematically illustrates one example of a switching memory device 200 that contains a memory element 112, and an optional current steering device 216, which are disposed between the electrodes 102 and 118. In one configuration, the current steering device 216 is an intervening electrical component, such as a p-n junction diode, p-i-n diode, transistor, or other similar device that is disposed between electrode 102 and memory element 112, or between the electrode 118 and memory element 112.

FIG. 2B schematically illustrates a switching memory device 200 that contains a memory element 112 and a diode type current steering device 216 that preferentially allows current to flow through the memory device 200 in a forward direction (“I⁺”). However, due to the non-ideal nature of real diodes, or by design of the current steering device 216, a reduced current can also flow in the opposing direction through the device by the application of a reverse bias to the electrodes 102 and 118.

FIG. 2C schematically illustrates a series array of switching memory devices 200A-200C that may be connected together to form part of a high-capacity nonvolatile memory integrated circuit. As illustrated in FIG. 2C, each of the switching memory devices 200A-200C may be connected internally in a fabricated chip package, or externally from a fabricated chip package, by use of the electrodes 102A-102C and 118A-118C.

During operation, such as a read operation, the state of a memory element 112 in the switching memory device 200 can be sensed by applying a sensing voltage (i.e., a “read” voltage V_{READ} (FIG. 2D)), such as applying about +0.5 volts (V), to the electrodes 102 and 118. Depending on its history, a memory element 112 that is addressed in this way may be in either a high resistance state or a low resistance state. The resistance of the memory element 112 therefore determines what digital data is being stored by the memory element 112. If the memory element 112 has a high resistance, for example, the memory element 112 may be said to contain a logic one (i.e., a “1” bit). If, on the other hand, the memory element 112 has a low resistance, the memory element 112 may be said to contain a logic zero (i.e., a “0” bit). During a write operation, the state of a memory element 112 can be changed by application of suitable “write” signals to an appropriate set of electrodes 102 and 118.

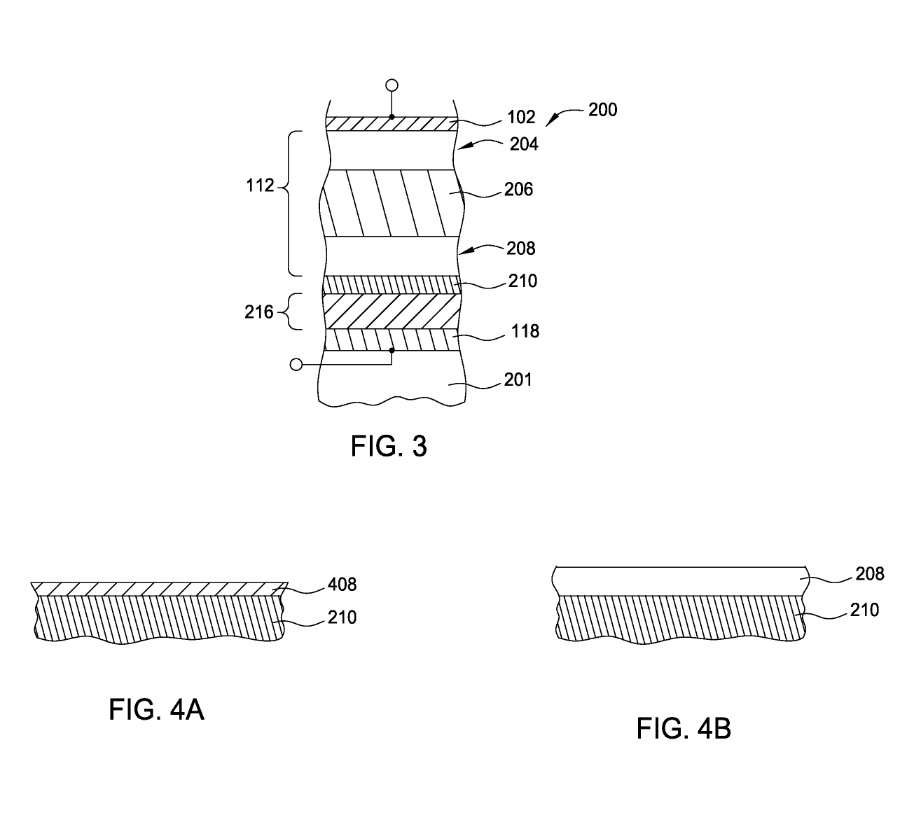

In some embodiments, the memory element 112 uses bipolar switching where “set” and “reset” voltages, used to alter the resistance of the memory element 112 from a high to a low resistance state, each have an opposite polarity relative to a common electrical reference. FIG. 2D is a logarithm of current (I) versus voltage (V) plot 251 for a bipolar switching curve 252 of a resistive switching type of memory element 112, and thus illustrates typical threshold values used to set and reset the contents of the memory element 112. In one example, initially, memory element 112 may be in a high resistance state (“HRS”, e.g., storing a logic one). The high resistance state of memory element 112 can be sensed by read and write circuitry 150 (FIG. 2A) using electrodes 102 and 118. For example, read and write circuitry 150 may apply a read voltage V_{READ} to memory element 112 and can sense the resulting “off” current (I_{OFF}) that flows through memory element 112. When it is desired to store a logic one in the memory element 112, the memory element 112 can be placed into its low-resistance state. This may be accomplished by using read and write circuitry 150 to apply a set voltage V_{SET} (e.g., −2 V to −4 V) across electrodes 102 and 118. In one configuration, applying a negative V_{SET} voltage to the memory element 112 causes the memory element 112 to switch to its low resistance state. In this region, the memory element 112 is changed so that, following removal of the set voltage V_{SET}, memory element 112 is characterized by a low resistance state. It is believed that the change in the resistive state of memory element 112 may occur because the reverse biasing of the device causes traps fabricated in a variable resistance layer 206 (FIG. 3), or VR layer 206, in the memory element 112 to be redistributed or filled (i.e., “trap-mediated”) during this process. However, the particular mechanism causing the change in the resistive state of memory element 112 is not limiting as to the inventions described herein and may occur due to other mechanisms not discussed herein. It should be noted that V_{SET} and V_{RESET} are generally referred to as “switching voltages” herein.

The low resistance state of the memory element 112 can be sensed using read and write circuitry 150. When a read voltage V_{READ} is applied to resistive switching memory element 112, the read and write circuitry 150 senses the relatively high “on” current value I_{ON}, indicating that the memory element 112 is in its low resistance state. When it is desired to store a logic zero in the memory element 112, the memory element 112 can once again be placed in its high resistance state by applying a positive reset voltage V_{RESET} (e.g., +2 V to +5 V) to the memory element 112. When read and write circuitry applies V_{RESET} to the memory element 112, the memory element 112 enters its high resistance state. When the reset voltage V_{RESET} is removed from the memory element 112, the memory element 112 is once again characterized by high resistance when the read voltage V_{READ} is applied. Voltage pulses can be used in the programming of the memory element 112. For example, a 1 ms, 10 μs, 5 μs, 500 ns, etc. square pulse can be used to switch the memory element 112. It may be desirable to adjust the length of the pulse depending on the amount of time needed to switch the memory element 112. While the discussion of the memory element 112 herein primarily provides bipolar switching examples, some embodiments of the memory elements 112 may use unipolar switching, where the set and reset voltages have the same polarity, without deviating from the scope of the invention described herein.

FIG. 3 is a schematic side cross-sectional view of a switching memory device 200 that is fabricated from a series of deposited layers according to one embodiment. The integrated series of layers used to form the switching memory device 200 shown in FIG. 3 are fabricated over, or integrated with and distributed over, portions of a surface of a substrate 201 (e.g., silicon substrate, SOI substrate). As shown in FIG. 3, the switching memory device 200 includes an electrode 102, a memory element 112, an intermediate electrode 210, a current steering device 216, and an electrode 118. It should be noted that, in some configurations, the switching memory device 200 does not contain a current steering device 216. In such configurations, the electrode 118 and the intermediate electrode 210 may both be the same element, or parts of a larger multilayered electrode element.

The electrode 102 and the electrode 118 are fabricated from conductive materials that have a desirable work function. In some configurations, the electrode 102 and electrode 118 are fabricated from different materials. In some embodiments, the electrodes have a work function that differs by between 0.1 and 1 electron volt (eV), such as between 0.4 and 0.6 eV. For example, the electrode 102 can be TiN, which has a work function of 4.5-4.6 eV, while the electrode 118 can be n-type polysilicon, which has a work function of approximately 4.1-4.15 eV. Other materials that may be used for the electrode 102 or 118 include p-type polysilicon, transition metals, transition metal alloys, transition metal nitrides, transition metal carbides, tungsten, tantalum nitride, molybdenum oxide, molybdenum nitride, iridium, iridium oxide, ruthenium, and ruthenium oxide. Other potential electrode materials include a titanium/aluminum alloy, nickel, tungsten nitride, tungsten oxide, aluminum, copper or silicon-doped aluminum, copper, hafnium carbide, hafnium nitride, niobium nitride, tantalum carbide, tantalum silicon nitride, titanium, vanadium carbide, vanadium nitride, and zirconium nitride.

As previously set forth, the current steering device 216 may be a diode that is used to select a memory element for access from amongst several memory elements, such as the several memory elements 112 of the array 100. The current steering device 216 may include two or more layers of semiconductor material that are appropriately doped to form a p-n junction diode or a p-i-n diode, for instance.

The intermediate electrode 210 is fabricated on the current steering device 216. The intermediate electrode 210 may be a layer of heavily-doped silicon, such as n-type polysilicon or p-type polysilicon.

The memory element 112 generally includes a variable resistance (VR) layer 206 and one or more interface and/or coupling layers. The VR layer 206 can be a metal oxide or other material that can be switched between at least two or more stable resistive states. For instance, the VR layer 206 may be a high bandgap material layer (e.g., bandgap >4 electron volts (eVs)), such as hafnium oxide (HfₓO_{y}), tantalum oxide (TaₓO_{y}), aluminum oxide (AlₓO_{y}), lanthanum oxide (LaₓO_{y}), yttrium oxide (YₓO_{y}), dysprosium oxide (DyₓO_{y}), ytterbium oxide (YbₓO_{y}) and zirconium oxide (ZrₓO_{y}). In some aspects, high bandgap materials are desirable because they are more insulating and prevent transient currents from damaging control circuitry in the switching memory device 200 while providing improved data retention. In other aspects, the VR layer 206 should not include a material with a bandgap so high that the VR layer 206 is unable to change its resistive state in a switching voltage is applied. In other examples, lower bandgap metal oxide materials can be used for the VR layer 206, such as titanium oxide (TiOₓ), nickel oxide (NiO)ₓ or cerium oxide (CeOₓ). In still other examples, a semiconductive metal oxide (p-type or n-type), such as zinc oxides (ZnₓO_{y}), copper oxides (CuₓO_{y}), and their nonstoichiometric and doped variants can be used for the VR layer 206.

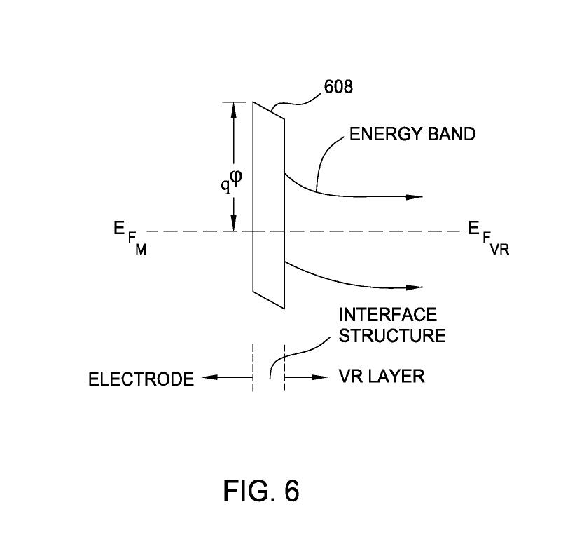

In the memory element shown in FIG. 3, a coupling layer 204 is disposed between the VR layer 206 and the electrode 102, and an interface layer 208 is disposed between the VR layer 206 and the intermediate electrode 210. Although depicted in FIG. 3, not all embodiments include the coupling layer 204. The coupling layer 204 and the interface layer 208 are generally configured to adjust the nonvolatile memory device's performance. For instance, the fabricated coupling layer 204 and the fabricated interface layer 208 comprise materials that lower the fabricated device's switching currents, reduce the device's forming voltage, and reduce the performance variation from one fabricated device 200 to another fabricated device 200 as described below with respect to FIG. 6.

The coupling layer 204 may be a metal oxide, such as zirconium oxide (ZrₓO_{y}) or aluminum oxide (AlₓO_{y}). Preferably, the coupling layer 204 is fabricated of a material that has a greater band gap than that of the VR layer 206. For instance, if the VR layer 206 is HfO₂ with a band gap of approximately 5.7 eV, the coupling layer 204 may be chosen to be Al₂O₃ with a band gap of approximately 8.4 eV. The coupling layer 204, thus, increases the barrier height at the interface between the electrode 102 and the VR layer 206. The increased barrier height reduces the magnitude of the current that flows through the device 200 due to increased energy required to move the carrier over or tunnel through the fabricated barrier so that the current is able to flow through the device, resulting in desirably lower switching current.

The interface layer 208 is an intentionally fabricated layer designed to provide a number of beneficial characteristics at the interface between the intermediate electrode 210 and the VR layer 206 as compared to allowing a native oxide or silicide to form between the intermediate electrode 210 and the VR layer 206. In one embodiment, the interface layer 208 is a layer of high-k material fabricated on the intermediate electrode 210 prior to fabricating the VR layer 206. Examples of suitable high-k materials include aluminum oxide (Al₂O₃), zirconium oxide (ZrO₂), yttrium oxide (Y₂O₃), silicon nitride (Si₃N₄), silicon oxynitride (SiON), and the like.

FIG. 6 schematically illustrates the band structure of an interface fabricated between the intermediate electrode 210 and the VR layer 206, in which the interface layer 208 is disposed between the electrode 210 and the VR layer 206. The interface layer 208 forms a blocking region 608 that inhibits the flow of current in either direction through the fabricated interface. The presence of the interface layer 208 naturally forms a barrier height (qφ) at the intermediate electrode 210. The size of the barrier height (qφ) is strongly dependent on the bandgap of the material used to form the interface layer 208. Thus, providing a suitable high-k material at the interface layer 208 increases the barrier height (e.g., increase of 1 eV to 5 eV compared to native silicon oxide) at the interface between the intermediate electrode 210 and the VR layer 206 due to the increased bandgap of the interface layer 208, which lowers the magnitude of current (e.g., I_{ON}, I_{OFF}) that can flow through the device during operation, resulting in desirably lower switching current of the device 200. Providing a suitable high-k material as the interface layer 208 also reduces the equivalent oxide thickness (EOT) of the dielectric layer stack fabricated in the device 200, allowing thinner layers to be used which results in desirably lower switching current and voltage.

In another embodiment, the interface layer 208 is a layer of high quality silicon oxide fabricated on the intermediate electrode 210. The ozone treatment provides a denser, higher quality layer of silicon oxide than the native silicon oxide naturally formed on the intermediate electrode 210, resulting in desirably lower switching current of the device 200.

The interface layer 208 also provides additional benefits, such as passivation at the surface of the intermediate electrode 210. In conventionally fabricated switching memory device, the interface region formed between the intermediate electrode 210 and the VR layer 206 generally contains many defects that can increase carrier recombination and prevent a good electrical contact from being formed between these fabricated adjacent layers. In general, the amount of carrier recombination is a function of how many dangling bonds (i.e., unterminated chemical bonds) are present at the interface. These unterminated chemical bonds act as defect traps, which can act as sites for carrier recombination and increase the resistance to the flow of the “on” and “off” currents through the fabricated device. Therefore, in one embodiment of the invention, a passivation layer 208 is fabricated at the interface between the intermediate electrode 210 and the VR layer 206 to passivate the defects found at the interface of the intermediate electrode 210. Since the number of defects can vary from one fabricated device 200 to the next, and from one region of the substrate on which the device is fabricated from another, the variability of the device performance can vary from device to device, and from one region of the substrate to another. Therefore, by fabricating the interface layer 208 at the electrode interface, which reduces the number of interfacial defects and passivates the interface surface, the device performance variability across a fabricated integrated circuit structure (e.g., array of fabricated devices) can be greatly reduced. In addition, better data retention can be achieved through passivating the interface of the intermediate electrode 210. In this sense, passivation of the interface layer prevents trapping of charged species during switching of the VR layer 206, which prevents degradation of switching current and voltage during switching of the VR layer 206.

In addition, the interface layer 208 provides an improved diffusion barrier between the intermediate electrode 210 and the VR layer 206. For example, during formation of the VR layer 206 (e.g., HfO₂), oxygen atoms may diffuse into the surface of the intermediate electrode 210 (e.g., polysilicon) and form a low quality silicon oxide layer, which may hinder the flow of current into the VR layer 206 resulting in elevated forming and/or switching currents and voltages. Addition of the interface layer 208, provides a diffusion barrier between the intermediate electrode 210 and the VR layer 206, resulting in a higher quality interface between the two layers, which has improved electrical properties.

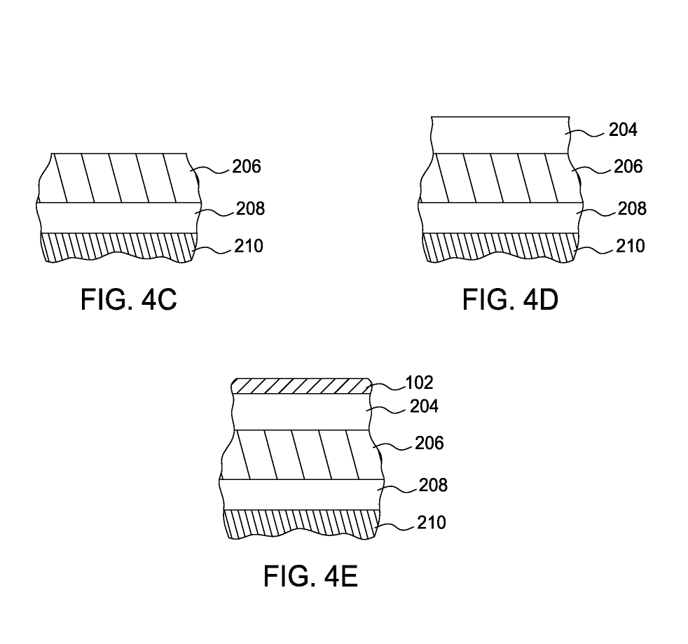

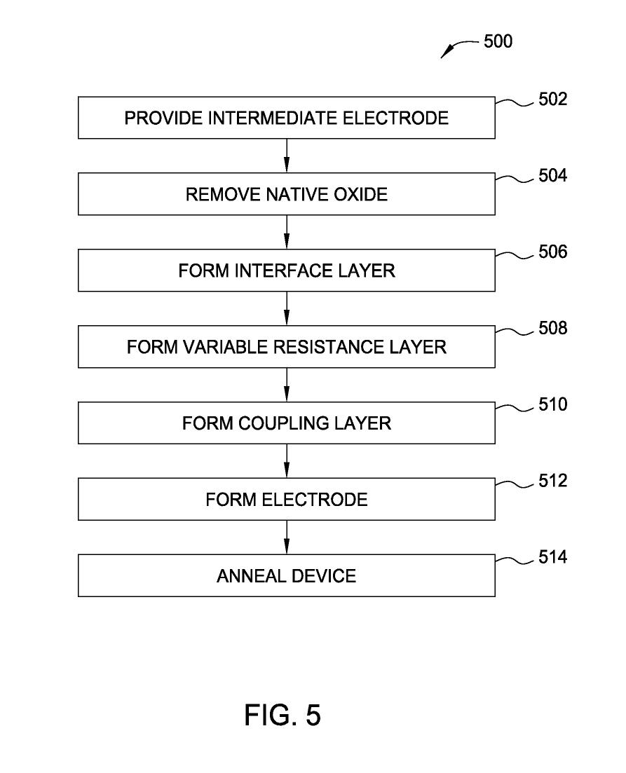

FIGS. 4A-4E are partial schematic depictions of the switching memory device 200 at various stages of formation. FIG. 5 is a schematic depiction of a process 500 for fabricating the switching memory device 200 as depicted in FIGS. 4A-4E. Referring to FIGS. 4A and 5, at step 502 an intermediate electrode 210 is provided having a native oxide layer 408 formed thereon. In one embodiment, the intermediate electrode 210 is a highly doped polysilicon layer with a native silicon oxide layer 408 thereon. In this context, the term native oxide refers to an oxide layer that naturally forms on the polysilicon layer due to natural exposure to oxygen. Although only the intermediate electrode 210 is depicted in FIGS. 4A-4E, the intermediate electrode 210 may be provided on a substrate (i.e., substrate 201 as provided in FIG. 3) having the steering device 216 and the electrode 118 fabricated thereon as well. Alternatively, in the case where no steering device 216 is provided, the depicted intermediate electrode 210 is the electrode 118.

At optional step 504 in FIG. 5, at least a portion of the native oxide layer 408 in FIG. 4A is removed from the intermediate electrode 210. In one embodiment the entire native oxide layer 408 is removed in step 504. In one embodiment, the intermediate electrode 210 is exposed to a cleaning solution, such as a solution of hydrogen fluoride (HF) and deionized (DI) water. The cleaning solution may be an aqueous solution that contains between about 0.1 and about 10% weight of HF that is maintained at a temperature between about 20 and about 30 degrees Celsius. In another embodiment, the native oxide layer 408 is removed using a buffered oxide etch (BOE), such as a mixture of ammonium fluoride (NH₄F) and hydrofluoric acid (HF). In another embodiment, the native oxide layer 408 is removed using a dry clean procedure in a plasma processing chamber. In this embodiment, the native oxide layer 408 is exposed to a plasma formed of NH₃ and NF₃ precursors, which reacts with the native oxide layer 408 to form a thin film on the intermediate electrode 210. The thin film is heated and sublimated into volatile gases, which are subsequently evacuated from the chamber.

In one embodiment, at step 506 in FIG. 5, and as depicted in FIG. 4B, the interface layer 208 is fabricated on the intermediate electrode 210 using a deposition process, such as atomic layer deposition (ALD), plasma enhanced atomic layer deposition (PEALD), chemical vapor deposition (CVD), plasma enhanced chemical vapor deposition (PECVD), physical vapor deposition (PVD), or the like. In one embodiment, the interface layer 208 is fabricated on the surface of the intermediate electrode 210 where the native oxide layer 408 was removed in step 504. ALD is used to deposit conformal layers with atomic scale thickness control. For depositing a metal oxide (e.g., Al₂O₃, ZrO₂), ALD is a multistep self-limiting process that includes the use of two reagents: a metal precursor (e.g., trimethylaluminum (TMA), tetrakisethylmethylaminozirconium (TEMEZr)) and an oxidizer (e.g., oxygen, ozone, water). The metal precursor is first introduced into a processing chamber containing the device having the intermediate electrode 210 and adsorbs on the surface of the intermediate electrode 210. Next, the oxidizer is introduced into the chamber and reacts with the adsorbed layer to form a deposited metal oxide layer. The process is repeated to form a number of successive layers that make up the completed interface layer 208. The interface layer 208 may be fabricated to a thickness between about 3 and about 10 angstroms. The processes may be performed at atmospheric or vacuum conditions at between about 200° C. and about 300° C.

In another embodiment, at step 506, the interface layer 208 in FIG. 4B is formed on the intermediate electrode 210 by performing a nitridation process on the native oxide layer 408 in FIG. 4A to form a SiON interface layer 208. In one example, the interface layer 208 is annealed in a nitrogen environment, such as NH₃, N₂O, NO, or the like. In this example, the partially fabricated device 200 is heated to a temperature between about 750 and about 900 degrees Celsius at a pressure of less than about 100 Torr for a time period between about 30 second and about 120 seconds. In another example, the SiON interface layer 208 is formed by plasma nitridation of the native oxide layer 408. In this example, the partially formed device 200 is exposed to plasma comprising a nitrogen source, such as nitrogen gas (N₂), NH₃, or combinations thereof. The plasma may further include an inert gas, such as helium, argon, or combinations thereof. The pressure in the chamber during the plasma exposure may be between about 1 mTorr and about 30 mTorr, and the temperature may be may be maintained at between about 200 and about 500 degrees Celsius. In one embodiment, the interface layer 208 is fabricated by performing an ozone treatment on the native oxide layer 408 as subsequently described below.

In another embodiment, at step 506, the interface layer 208 is fabricated by intentionally fabricating a high quality oxide layer on the intermediate electrode 210. In one embodiment, the oxide layer is fabricated by performing an ozone treatment on the native oxide layer 408. In another embodiment, the oxide layer is fabricated by performing an ozone treatment on the intermediate electrode 210. The ozone treatment may be a plasma process performed at between about 200° C. and about 300° C. Ozone may be flown into a plasma chamber at between about 500 sccm and about 1000 sccm from about 30 seconds to about 10 minutes during the ozone treatment. The ozone exposure may be continuous or pulsed. Alternatively, the ozone treatment may be performed after step 408 rather than prior to step 408. In another embodiment, the oxide layer is fabricated by using chemical treatment. In this embodiment, a mixture of ammonium hydroxide (NH₄OH), hydrogen peroxide (H₂O₂), and de-ionized (DI) water or APM mixture. The ratio of NH₄OH to H₂O₂ to DI water may be from about 1:1:5 to about 1:1:50. The surface of the intermediate electrode 210 is exposed to the APM mixture at a temperature between about 25° C. and about 75° C. Following the chemical oxide treatment the surface may be exposed to a dilute hydrochloric acid (HCl), such as 1:100 HCl to DI water. The ozone treatment or chemical treatment provides a denser, higher quality layer of silicon oxide than the native silicon oxide naturally formed on the intermediate electrode 210, resulting in desirably lower switching current of the device 200. In one embodiment, the above described nitridation process may be performed after the ozone or chemical treatment at step 506.

Referring to FIGS. 4C and 5, at step 508, the VR layer 206 is deposited on the interface layer 208 using a deposition process. Similar to the interface layer 208, the metal oxide VR layer 206 (e.g., HfO₂, Ta₂O₅, Al₂O₃, La₂O₃, Y₂O₃, Dy₂O₃, Yb₂O₃, ZrO₂, NB₂O₅, ZyALD™) is deposited to a desired thickness using a deposition process, such as ALD, PEALD, CVD, PECVD, PVD or the like. The VR layer 206 may be formed to a thickness of between about 15 and about 100 angstroms.

Referring to FIGS. 4D and 5, at step 510, the coupling layer 204 is deposited on the VR layer 206 using a deposition process. Similar to the interface layer 208 and the VR layer 206, the metal oxide coupling layer 204 (e.g., Al₂O₃, ZrO₂, NB₂O₅) is deposited to a desired thickness using a deposition process, such as ALD, PEALD, CVD, PECVD, PVD, or the like. The coupling layer 204 may be fabricated to a thickness of between about 3 and about 20 angstroms.

At step 512 in FIG. 5, the electrode 102 is fabricated on the coupling layer 204 as shown in FIG. 4E. The electrode 102 may be deposited using a deposition process, such as a physical vapor deposition process or a chemical vapor deposition process.

At step 514, the fabricated device 200 is annealed at a temperature of between about 700° C. and about 800° C. at atmospheric pressure for between about 30 seconds and about 120 seconds. In one example, the device 200 is annealed using a hydrogen/argon mixture (e.g., 2-10% hydrogen, 90-98% argon), although other anneals such as vacuum anneals, oxidizing anneals, nitrogen anneals, etc. can be used. The process performed at step 514 generally activates the various layers formed in the switching memory device 200.

Thus, a resistive switching nonvolatile memory device having an interface layer disposed between a highly doped silicon electrode and a variable resistance layer fabricated in the nonvolatile memory device and methods of fabricating the same are provided. In one embodiment, the interface layer is a high-k layer having a lower electrical effective oxide thickness than native silicon oxide to act as a diffusion barrier between the variable resistance layer and the silicon electrode. The high-k interface layer provides increased barrier height at the interface between the silicon electrode and the variable resistance layer, resulting in desirably lower switching current of the fabricated device. The high-k interface layer may be fabricated by depositing a high-k material layer on the silicon electrode after removal of any native silicon oxide. Alternatively, the high-k interface layer may be fabricated by performing a nitrogen treatment on a fabricated silicon oxide layer. In another embodiment, the interface layer is a fabricated silicon oxide layer resulting in an improved diffusion barrier between the variable resistance layer and the silicon electrode. In all embodiments, the interface layer also passivates the surface of the silicon electrode.

In the diagrams, the formation of a first layer “over” another second layer is depicted as a relationship that has a direct contact between the first layer and the second layer. It shall be noted that the relationship of “over” may include a non-contact relationship, since the function of the various layers does not necessarily implicate a direct contact relationship.

The foregoing is merely illustrative of the principles of this invention and various modifications can be made by those skilled in the art without departing from the scope and spirit of the invention as defined by the claims that follow.

1. A method of fabricating a nonvolatile memory element, comprising:
removing at least a portion of a native oxide layer from a surface of a first electrode, the first electrode comprising silicon;
fabricating a high-k interface layer above the surface of the first electrode from which the native oxide layer was removed;
fabricating a variable resistance layer over the high-k interface layer; and
forming a second electrode over the variable resistance layer.

2. The method of claim 1, wherein removing at least a portion of the native oxide layer comprises performing a buffered oxide etch process.

3. The method of claim 1, wherein removing the native oxide layer comprises performing an HF clean process.

4. The method of claim 1, wherein the high-k interface layer comprises a material selected from the list consisting of aluminum oxide and zirconium oxide.

5. The method of claim 1, further comprising fabricating a high-k coupling layer between the variable resistance layer and the second electrode.

6. The method of claim 1, wherein the first electrode is disposed on a current steering device structure.

7. The method of claim 1, further comprising heating the nonvolatile memory element to a temperature between about 700 degrees Celsius and about 800 degrees Celsius.

8. The method of claim 1, wherein removing at least a portion of the native oxide layer comprises performing a plasma dry-clean process.

9. A method of fabricating a non-volatile memory element, comprising:
performing a nitrogen or ozone treatment on a native oxide layer disposed above a first electrode;
fabricating a variable resistance layer over the first electrode; and
forming a second electrode over the variable resistance layer.

10. The method of claim 9, wherein the nitrogen treatment is a nitrogen anneal.

11. The method of claim 9, wherein the nitrogen treatment is a plasma nitridation process.

12. A method of fabricating a nonvolatile memory element, comprising:
removing a native oxide layer from a first electrode;
fabricating an oxide layer on the first electrode;
fabricating a variable resistance layer over the first electrode; and
fabricating a second electrode over the variable resistance layer.

13. The method of claim 12, wherein fabricating the oxide layer is performed using an ozone treatment.

14. The method of claim 12, wherein the oxide layer is fabricated using a chemical oxide treatment.

15. The method of claim 12, further comprising performing a nitridation process to the oxide layer.

16. The method of claim 12, wherein the first electrode is disposed on a current steering device structure.

17. The method of claim 16, wherein a high-k coupling layer is formed between the variable resistance layer and the second electrode.

18. The method of claim 17, further comprising heating the nonvolatile memory element to a temperature of between about 700 degrees Celsius and about 800 degrees Celsius.

19. The method of claim 12, wherein removing the native oxide layer from the first electrode comprises performing a buffered oxide etch process.

20. The method of claim 12, wherein removing the native oxide layer from the first electrode comprises performing an HF clean process.
